(19) United States
(12) Patent Application Publication
(10) Pub. No.: US 2025/0343093 A1
(43) Pub. Date: Nov. 6, 2025

(54) SEMICONDUCTOR DEVICE

(71) Applicant: Mitsubishi Electric Corporation, Tokyo (JP)

(72) Inventors: Mao SAWAKAWA, Tokyo (JP); Yoshitaka MIYAJI, Tokyo (JP); Hiroki SHIOTA, Tokyo (JP); Atsushi YAMATAKE, Tokyo (JP)

(73) Assignee: Mitsubishi Electric Corporation, Tokyo (JP)

(21) Appl. No.: 18/870,692

(22) PCT Filed: Jun. 10, 2022
(86) PCT No.: PCT/JP2022/023460

§ 371 Date: Dec. 2, 2024

(51) Int. Cl. H01L 23/367; H01L 23/16; H01L 23/31

(52) U.S. Cl. CPC H01L 23/367; H01L 23/16; H01L 23/3107

(57) ABSTRACT

A semiconductor device according to one aspect of the present disclosure includes: a semiconductor package in which a heat spreader, a semiconductor chip provided on one surface of the heat spreader, and an electrode terminal electrically connected to the semiconductor chip are sealed with resin, the semiconductor package having a bottom surface at which another surface of the heat spreader is exposed from the sealing resin, an insulation sheet provided at the bottom surface of the semiconductor package; and a heat sink having a recess in which the bottom surface of the semiconductor package is stored, a depth of the recess being greater than a thickness of the insulation sheet, a bottom surface of the recess and the bottom surface of the semiconductor package being joined to each other via the insulation sheet, thus supporting the semiconductor package in the recess.

### TECHNICAL FIELD

The present disclosure relates to a semiconductor device.

### BACKGROUND ART

Among semiconductor devices, for example, a semiconductor device used for power conversion is used in power control of a wide variety of apparatuses such as industrial apparatuses, home appliances, information terminals, automobiles, and trains. A specific example is an inverter for converting DC power to AC power. In particular, in a semiconductor device that operates with increased current and increased voltage, it is necessary to ensure a high insulation property and efficiently release heat generated through operation to the outside. In addition, some apparatuses can be used under severe environments such as high temperature, low temperature, low pressure, and vibration, and therefore stability of joining between members is required for keeping stable reliability even under such a severe environment. For example, in Patent Document 1, a part of a heat sink is embedded in a semiconductor package, whereby displacement and separation between the semiconductor package, an insulation sheet, and the heat sink are prevented.

### CITATION LIST

### Patent Document

Patent Document 1; Japanese Laid-Open Patent Publication No. 2013-115167

### SUMMARY OF THE INVENTION

### Problem to be Solved by the Invention

However, in the conventional configuration as shown in Patent Document 1, since the heat sink and the insulation sheet are covered by the semiconductor package, the contact area between the heat sink and a cooling medium is limited, leading to a problem that a heat dissipation property is reduced.

The present disclosure has been made to solve the above problem, and an object of the present disclosure is to suppress reduction in a heat dissipation property while preventing displacement and separation between a semiconductor package, an insulation sheet, and a heat sink by covering the semiconductor package and the insulation sheet by the heat sink.

### Means to Solve the Problem

A semiconductor device according to one aspect of the present disclosure includes: a semiconductor package in which a heat spreader, a semiconductor chip provided on one surface of the heat spreader, and an electrode terminal electrically connected to the semiconductor chip are sealed with resin, the semiconductor package having a bottom surface at which another surface of the heat spreader is exposed from the sealing resin, the electrode terminal protruding from at least one of a side surface and a top surface; an insulation sheet provided at the bottom surface of the semiconductor package; and a heat sink having a recess in which the bottom surface of the semiconductor package is stored, a depth of the recess being greater than a thickness of the insulation sheet, a bottom surface of the recess and the bottom surface of the semiconductor package being joined to each other via the insulation sheet, thus supporting the semiconductor package in the recess.

### Effect of the Invention

According to the present disclosure, it is possible to suppress reduction in a heat dissipation property while preventing displacement and separation of joining parts of the semiconductor package, the insulation sheet, and the heat sink by covering the semiconductor package and the insulation sheet by the heat sink.

### BRIEF DESCRIPTION OF THE DRAWINGS

FIG. 1 is a top view of a semiconductor device 100 according to embodiment 1.

FIG. 2 is a sectional view along line A-A of the semiconductor device 100 according to embodiment 1 in a case of applying a wire bonding structure.

FIG. 3 is a sectional view along line A-A of the semiconductor device 100 according to embodiment 1 in a case of applying a direct lead bonding structure.

FIG. 4 is a top view showing an example in which a plurality of semiconductor packages 110 are mounted to one heat sink 8 in the semiconductor device 100 according to embodiment 1.

FIG. 5 is a top view of a semiconductor device 200 according to embodiment 2.

FIG. 6 is a sectional view along line B-B of the semiconductor device 200 according to embodiment 2.

FIG. 7 is a sectional view along line C-C of the semiconductor device 200 according to embodiment 2.

FIG. 8 is a sectional view along line A-A of a semiconductor device 300 according to embodiment 3.

FIG. 9 is a bottom view of a semiconductor package 310 of the semiconductor device 300 according to embodiment 3.

FIG. 10 is a bottom view of a semiconductor package 310 of the semiconductor device 300 according to a modification of embodiment 3.

FIG. 11 is a top view of a semiconductor device 400 according to embodiment 4.

FIG. 12 is a sectional view along line D-D of the semiconductor device 400 according to embodiment 4.

FIG. 13 is a top view of the semiconductor device 400 according to a modification of embodiment 4.

FIG. 14 is a sectional view along line E-E of the semiconductor device 400 according to the modification of embodiment 4.

### DESCRIPTION OF EMBODIMENTS

Hereinafter, a semiconductor device according to embodiments of the present disclosure will be described with reference to the drawings. Components having the same or corresponding functions may be denoted by the same reference characters, and repeated description thereof may be omitted.

### Embodiment 1

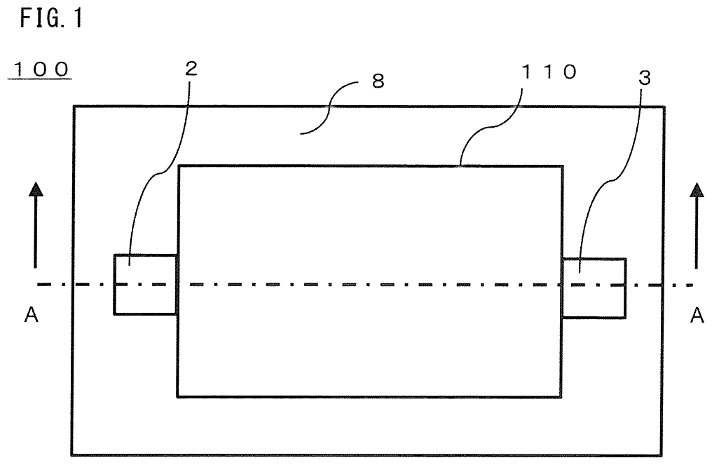

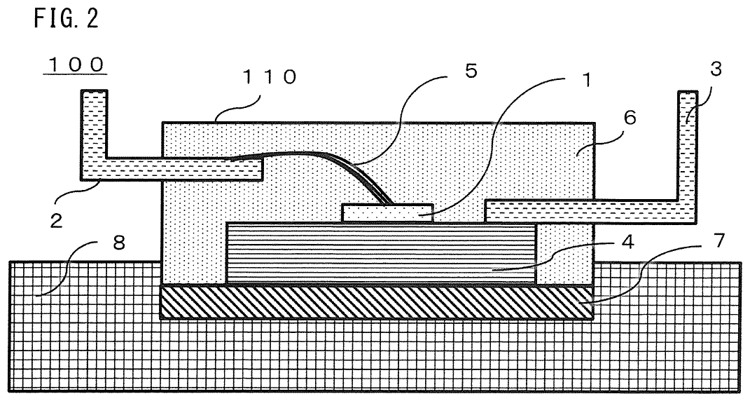

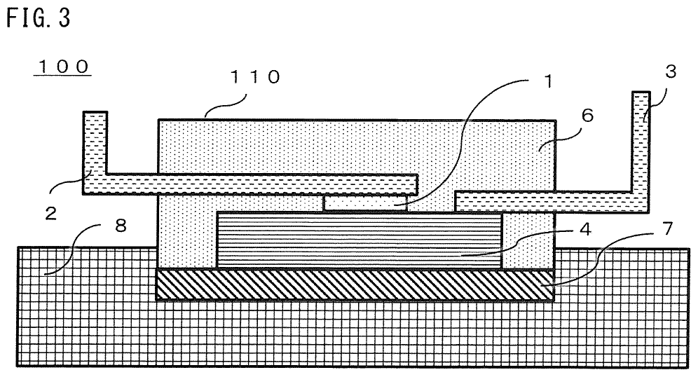

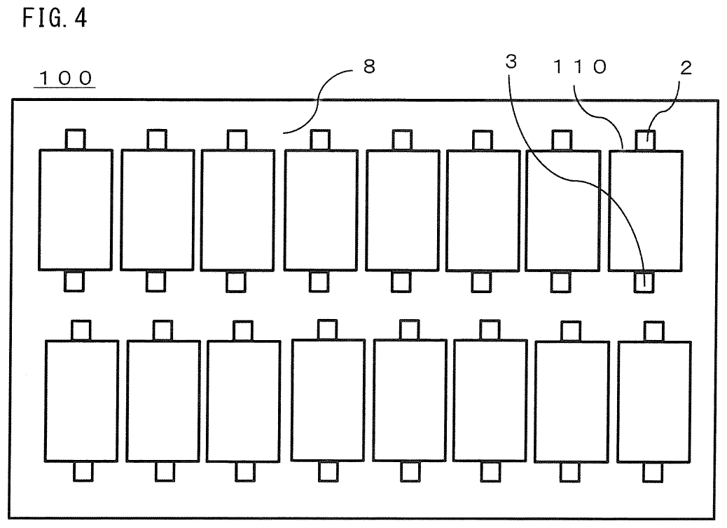

FIG. 1 is a top view of a semiconductor device 100 according to embodiment 1, and FIG. 2 is a sectional view along line A-A in FIG. 1, of the semiconductor device according to embodiment 1 in a case of applying a wire bonding structure. FIG. 3 is a sectional view along line A-A in FIG. 1, of the semiconductor device according to embodiment 1 in a case of applying a direct lead bonding structure. FIG. 4 is a top view showing a modification in which a plurality of semiconductor packages are provided on one heat sink 8 in the semiconductor device according to embodiment 1. As shown in FIG. 1, a semiconductor package 110 is located on the heat sink 8 and has a first electrode terminal 2 on one side of the semiconductor package 110 and a second electrode terminal 3 on another side. As shown in FIG. 2, a recess in which a bottom surface of the semiconductor package 110 is stored and joined is formed at one surface of the heat sink 8, and the semiconductor package 110 is joined to a bottom surface of the recess via an insulation sheet 7. Further, the semiconductor package 110 is supported by a side wall of the recess formed in the heat sink 8. The semiconductor package 110 includes a heat spreader 4, a semiconductor chip 1 provided on one surface of the heat spreader 4, the first electrode terminal 2 electrically joined to the semiconductor chip 1 via a wire 5, and the second electrode terminal 3 electrically joined to the semiconductor chip 1 via the heat spreader 4, and is sealed with sealing resin 6. Another surface of the heat spreader 4 is the surface of the semiconductor package 110 that is joined to the heat sink 8 via the insulation sheet 7, and is exposed to the outside of the semiconductor package 110. The recess of the heat sink 8 only has to be formed such that the bottom surface of the semiconductor package 110 is stored in the recess and the semiconductor package 110 is supported by at least a part of the side wall of the recess. Therefore, it suffices that the base area of the recess is at least larger than the area of the surface of the semiconductor package 110 joined via the insulation sheet 7. Further, since the semiconductor package 110 is supported by at least a part of the side wall of the recess, it suffices that the thickness of the insulation sheet 7 is smaller than the height of the side wall of the recess.

Here, the semiconductor chip 1 includes one or a plurality of elements for large current control, such as an insulated gate transistor (IGBT), a metal-oxide-semiconductor field-effect transistor (MOS-FET), or a diode. In FIG. 2, only one semiconductor chip 1 is shown, but a plurality of semiconductor chips may be mounted. As a material of the semiconductor chip 1, silicon (Si) may be used. Alternatively, a wide bandgap semiconductor material such as silicon carbide (SiC), gallium nitride (GaN), or diamond (C) may be used. In a case of using a wide bandgap semiconductor for the semiconductor chip 1, as compared to a case of using Si as a material of the semiconductor chip 1, power loss can be reduced and therefore power consumption of the semiconductor device 100 can be reduced. Further, in the case of using a wide bandgap semiconductor for the semiconductor chip 1, as compared to a case of using Si as a material of the semiconductor chip 1, the heat resistance is higher and operation can be performed at a higher temperature, and therefore the tolerance in thermal designing is widened, whereby the size of the semiconductor device 100 can be reduced.

The first electrode terminal 2 and the second electrode terminal 3 are components serving for electric connection between the inside and the outside of the semiconductor device 100. As materials of the first electrode terminal 2 and the second electrode terminal 3, metal having a high electric conductivity is preferably used, and for example, copper is preferably used. As materials of the first electrode terminal 2 and the second electrode terminal 3, examples other than copper include aluminum, iron, and an alloy thereof. In FIG. 2, the first electrode terminal and the second electrode terminal protrude outward from side surfaces of the semiconductor package 110. However, each terminal may protrude outward from a top surface of the semiconductor package 110. That is, the first electrode terminal and the second electrode terminal may protrude from at least one of a side surface and a top surface of the semiconductor package 110. Here, the semiconductor device including one electrode terminal as each of the first electrode terminal and the second electrode terminal is shown, but a plurality of electrode terminals may be provided as each of the first electrode terminal and the second electrode terminal. In accordance with the specifications of the semiconductor device, another electrode terminal may be provided in addition to the first electrode terminal and the second electrode terminal.

The heat spreader 4 is a component for dissipating heat generated through driving of the semiconductor chip 1, to the outside of the semiconductor package 110. In FIG. 2, the shape of the heat spreader 4 is a rectangular parallelepiped shape, as an example. However, the shape of the heat spreader 4 is not limited thereto and may be another shape such as a trapezoidal shape, a semi-cylindrical shape, ox a columnar shape. As a material of the heat spreader 4, metal having a high thermal conductivity is preferably used, and for example, copper is preferably used. As a material of the heat spreader 4, examples other than copper include aluminum, iron, and an alloy thereof.

The wire 5 is a component electrically connecting the semiconductor chip 1 and the first electrode terminal 2, and is preferably made of metal that can be easily worked and has a high electric conductivity, e.g., gold, copper, or aluminum. The wire 5 may be connected as a signal line for controlling power of the semiconductor chip 1, and in this case, the wire 5 serves to transmit a control signal from the outside of the semiconductor package 110 to the semiconductor chip 1. As shown in FIG. 3, the semiconductor chip 1 and the first electrode terminal 2 may be direct-lead-bonded, whereby the wire 5 may be omitted.

The sealing resin 6 is an insulating sealant which seals the heat spreader 4, the semiconductor chip 1, the wire 5, the first electrode terminal 2, and the second electrode terminal 3, to form the semiconductor package 110. An electric field is particularly high around an outer periphery of the semiconductor chip 1, and therefore the entire semiconductor chip 1 needs to be covered. As a material of the sealing resin 6, resin having a high insulation property, such as epoxy, polyimide, polyamide, or polyamide-imide, or a mixture obtained by adding silica, alumina, aluminum nitride, boron nitride, or the like to resin having a high insulation property, such as epoxy, polyimide, polyamide, or polyamide-imide, may be used. The same function can be obtained by using a material having a relative permittivity of 20 or less and a volume resistivity of 10¹⁰ Ω·cm or greater in a driving temperature range of the semiconductor device. It is required that, in molding, the sealing resin 6 does not include a factor such as a void that impairs the insulation property, and does not separate from an enclosed object due to an external factor such as vibration or heat. Therefore, the sealing resin 6 is preferably formed by transfer molding using a mold.

The insulation sheet 7 is a component for insulating the heat spreader 4 and the heat sink 8 from each other and dissipating heat from the heat spreader 4 to the heat sink 8. In order to prevent displacement and separation between the semiconductor package 110 and the heat sink 8, the insulation sheet 7 is interposed in a half-cured state between the semiconductor package 110 and the heat sink 8 and then is pressed and heated to be cured. A material of the insulation sheet 7 is resin having a high insulation property, such as epoxy, polyimide, polyamide, or polyamide- imide, or a mixture obtained by adding silica, alumina, aluminum nitride, boron nitride, or the like to resin such as epoxy, polyimide, polyamide, or polyamide-imide. As a material of the insulation sheet 7, silicone rubber, urethane rubber, or thermosetting elastomer, which has a lower elastic modulus than resin such as epoxy, polyimide, polyamide, or polyamide-imide, may be included. In this case, the insulation sheet 7 has elasticity and can absorb vibration, thus providing high vibration resistance advantageously. The insulation sheet 7 preferably has an increased thickness in order to enhance the insulation property, or preferably has a decreased thickness in order to enhance the heat dissipation property. In order to ensure an insulation property and a heat dissipation property, for example, the insulation sheet 7 preferably has a thickness of 20 μm to 500 μm in a case of using resin having a high insulation property, such as epoxy, polyimide, polyamide, polyamide-imide, silicone rubber, urethane rubber, or thermosetting elastomer, or preferably has a thickness not greater than approximately 2 mm in a case of using a mixture including a large amount of a ceramic filler having a high heat dissipation property.

The heat sink 8 is a component serving to dissipate heat of the semiconductor device 100. In the present disclosure, the semiconductor package 110 is joined via the insulation sheet 7 to the bottom surface of the recess provided to the heat sink 8, thus serving to support the semiconductor package 110 by the side wall of the recess. As a material of the heat sink 8, metal having a high thermal conductivity is preferably used, and for example, copper is preferably used. As a material of the heat sink 8, examples other than copper include aluminum, iron, and an alloy thereof. Although not shown, heat dissipation fins as a structure having a large surface area for performing efficient heat exchange may be connected to the heat sink 8. In this case, heat of the semiconductor device can be more efficiently dissipated, and if the heat sink 8 is integrated with heat dissipation fins, even more efficient heat dissipation can be performed.

FIG. 4 is a top view showing an example in which a plurality of semiconductor packages 110 are mounted to one heat sink 8 in the semiconductor device 100 according to embodiment 1. Also in the case where a plurality of semiconductor packages are mounted to one heat sink 8 as shown in FIG. 4, the same effects as described above can be obtained.

The semiconductor device configured as described above includes: a semiconductor package in which a heat spreader, a semiconductor chip provided on one surface of the heat spreader, a first electrode terminal electrically connected to the semiconductor chip, and a second electrode terminal electrically connected to the semiconductor chip are sealed with resin, the semiconductor package having a bottom surface at which another surface of the heat spreader is exposed from the sealing resin, the first electrode terminal and the second electrode terminal protruding from at least one of a side surface and a top surface of the semiconductor package; an insulation sheet provided at the bottom surface of the semiconductor package and covering at least the surface at which the other surface of the heat spreader is exposed; and a heat sink having a recess in which the bottom surface of the semiconductor package is stored, a depth of the recess being greater than a thickness of the insulation sheet, a bottom surface of the recess and the bottom surface of the semiconductor package being joined to each other via the insulation sheet, thus supporting the semiconductor package in the recess. Since the semiconductor package is joined via the insulation sheet to the recess formed in the heat sink, the heat sink is joined without being covered by the semiconductor package. In addition, since the semiconductor package is supported by the side wall of the recess, displacement and separation of joining parts of the semiconductor package, the insulation sheet, and the heat sink are prevented.

In a case where the semiconductor device has the semiconductor package of which at least one of the first electrode terminal or the second electrode terminal protrudes from a side surface, the depth of the recess of the heat sink is set to be greater than the thickness of the insulation sheet and smaller than the minimum length from the bottom surface of the semiconductor package to the positions where the first electrode terminal and the second electrode terminal protrude, whereby the same function can be obtained.

Thus, the configuration of the semiconductor device described in embodiment 1 can provide a semiconductor device in which reduction in a heat dissipation property is suppressed while displacement and separation of joining parts of a semiconductor package, an insulation sheet, and a heat sink are prevented.

### Embodiment 2

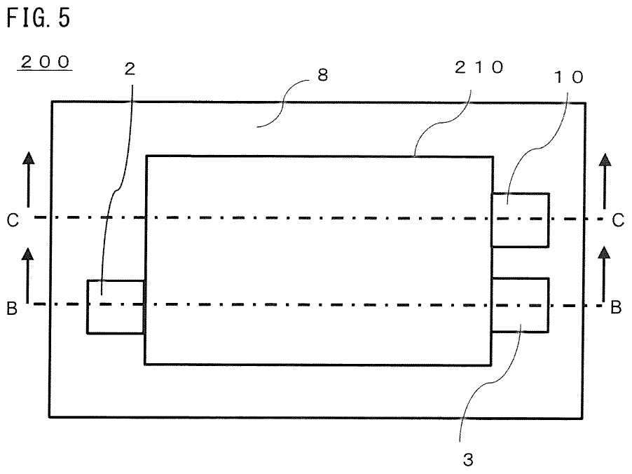

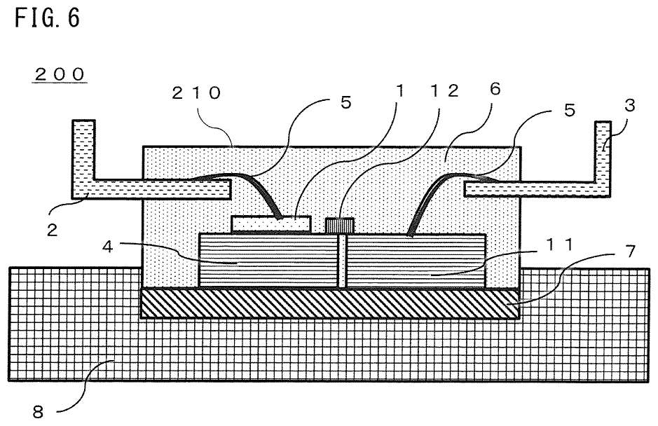

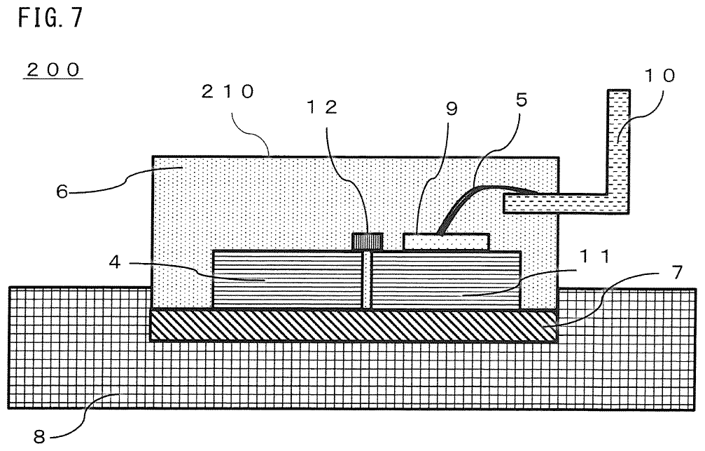

FIG. 5 is a top view of a semiconductor device 200 according to embodiment 2. FIG. 6 shows a sectional view along line B-B in FIG. 5, and FIG. 7 shows a sectional view along line C-C in FIG. 5. As shown in FIG. 5, the semiconductor device 200 includes a semiconductor package 210 having a first electrode terminal 2, a second electrode terminal 3, and a third electrode terminal 10. As shown in FIG. 6 and FIG. 7, a recess in which a bottom surface of the semiconductor package 210 is stored and joined is formed at one surface of the heat sink 8, and the semiconductor package 210 is joined and supported in the recess of the heat sink 8 via the insulation sheet 7. As shown in FIG. 6, the semiconductor package 210 has a heat spreader 4 and a heat spreader 11, and the heat spreader 4 and the heat spreader 11 are electrically connected via a bridge 12. A semiconductor chip 1 is provided on the heat spreader 4, and the semiconductor chip 1 and the first electrode terminal 2 are electrically connected via a wire 5. A semiconductor chip 9 is provided on the heat spreader 11, and the semiconductor chip 9 and the third electrode terminal 10 are electrically connected via a wire 5. The heat spreader 11 and the second electrode terminal 3 are electrically connected via a wire 5. The semiconductor chip 1 and the semiconductor chip 9 can be driven at different timings.

Here, the bridge 12 is a component connecting the heat spreader 4 and the heat spreader 11. As a material of the bridge 12, metal having a high electric conductivity is preferably used, and for example, copper is preferably used. As a material of the bridge 12, examples other than copper include aluminum, iron, and an alloy thereof. A wire 5 may be used instead of the bridge 12.

Although a configuration having two semiconductor chips that can be driven at different timings is shown in embodiment 2, a configuration having three or more semiconductor chips can also be adopted.

In the semiconductor device configured as described above, since the semiconductor package is joined via the insulation sheet to the recess which is formed in the heat sink and in which the bottom surface of the semiconductor package is stored and joined, the heat sink is joined without being covered by the semiconductor package. In addition, since the semiconductor package in the present embodiment is supported by the side wall of the recess, displacement and separation of joining parts of the semiconductor package, the insulation sheet, and the heat sink are prevented. Further, in the semiconductor device according to the present embodiment, for example, where a potential when the semiconductor chip 1 is driven is denoted by HV, power control can be performed at three levels of 0, HV, and 2AV, and by applying a configuration having two or more semiconductor chips, power control at three or more levels can be performed.

Thus, the configuration of the semiconductor device described in embodiment 2 can provide a semiconductor device that can perform power control at three or more levels, in addition to the same effects as in embodiment 1.

### Embodiment 3

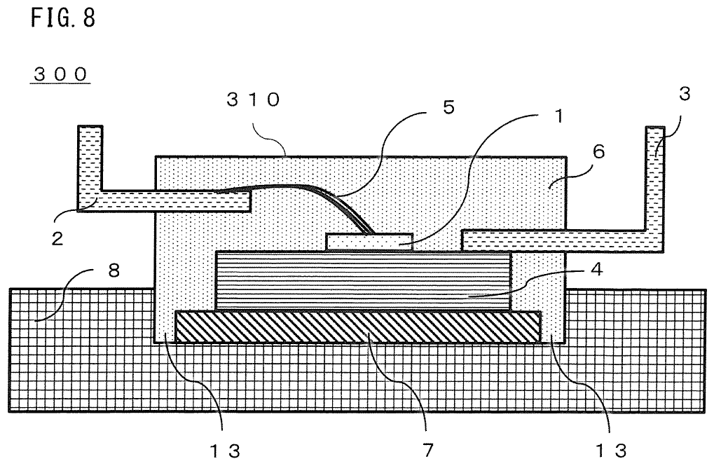

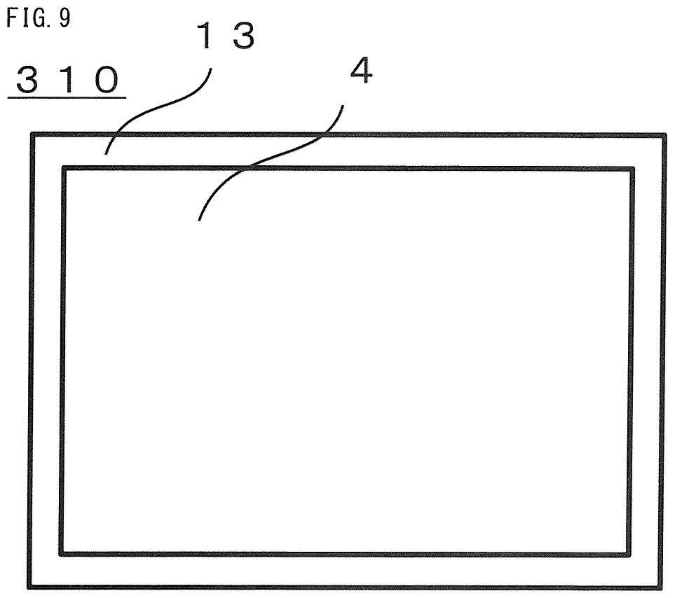

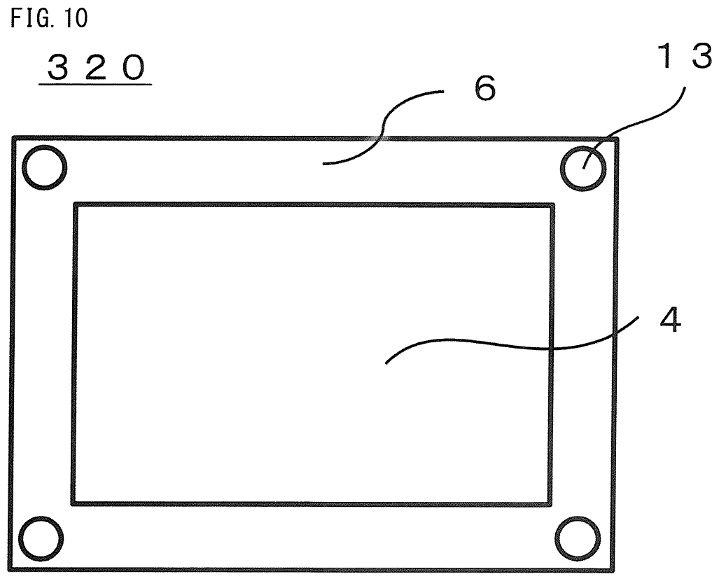

FIG. 8 is a sectional view of a semiconductor device 300 according to embodiment 3 along the same line as line A-A in FIG. 1. A top view of the semiconductor device of embodiment 3 is the same as in FIG. 1. FIG. 9 is a bottom view of a semiconductor. package 310 of the semiconductor device according to embodiment 3. FIG. 10 is a bottom view of a semiconductor package 320 of the semiconductor device 300 according to a modification of embodiment 3, which can provide the same effects as in embodiment 3. As shown in FIG. 8, the semiconductor package 310 has a protrusion 13 formed by sealing resin 6 on the plane including the surface of the heat spreader 4 that contacts with the insulation sheet 7, and protruding toward the bottom surface of the recess from the plane including the surface of the heat spreader 4 that contacts with the insulation sheet 7. The protrusion 13 is continuously formed at a constant height which is smaller than the thickness of the insulation sheet 7. Therefore, the protrusion 13 directly contacts with the bottom surface of the recess not via the insulation sheet 7, the other surface of the heat spreader 4 is joined to the bottom surface of the recess via the insulation sheet 7, and the thickness of the insulation sheet 7 is defined by the height of the protrusion 13. As shown in FIG. 9, the protrusion 13 is formed continuously around the outer periphery of the lower surface of the semiconductor package 310. The protrusion 13 may have any shape as long as, when the semiconductor package 310 is placed on a flat surface with the protrusion 13 directed downward, the semiconductor package 310 stands stably, and the thickness of the insulation sheet 7 is defined by the height of the protrusion 13. For example, in a modification shown in FIG. 10, columnar protrusions 13 having the same height may be provided at four corners of the lower surface of the semiconductor package 310 which is opposed to the bottom surface of the recess.

In the semiconductor device configured as described above, since the semiconductor package is joined via the insulation sheet to the recess formed in the heat sink, the heat sink is joined without being covered by the semiconductor package. In addition, since the semiconductor package is supported by the side wall of the recess, displacement and separation of joining parts of the semiconductor package, the insulation sheet, and the heat sink are prevented. Further, the semiconductor package in the present embodiment has a protrusion continuously formed at a constant height or a plurality of protrusions having equal heights, the protrusion or the plurality of protrusions being formed by the sealing resin on the plane including the surface of the heat spreader that contacts with the insulation sheet, and protruding toward the bottom surface of the recess from the plane including the surface of the heat spreader that contacts with the insulation sheet. The height of the protrusion or the plurality of protrusions is smaller than the thickness of the insulation sheet before the semiconductor package, the insulation sheet, and the heat spreader are joined, and the protrusion or the plurality of protrusions contact with the bottom surface of the recess not via the insulation sheet. The other surface of the heat spreader presses the insulation sheet, and the other surface of the heat spreader is joined to the bottom surface of the recess via the insulation sheet. With this configuration, in the semiconductor device according to the present embodiment, the interval between the other surface of the heat spreader and the bottom surface of the recess is defined by the protrusion, and variation in the thickness of the insulation sheet occurring when the semiconductor package, the insulation sheet, and the heat sink are joined is suppressed. Thus, tilting of a joining plane between the semiconductor package and the heat sink is suppressed.

Thus, the configurations of the semiconductor device described in embodiment 3 and the modification thereof can provide a semiconductor device in which tilting of a joining plane between a semiconductor package and a heat sink is suppressed, whereby stability in manufacturing is improved, in addition to the same effects as in embodiment 1.

### Embodiment 4

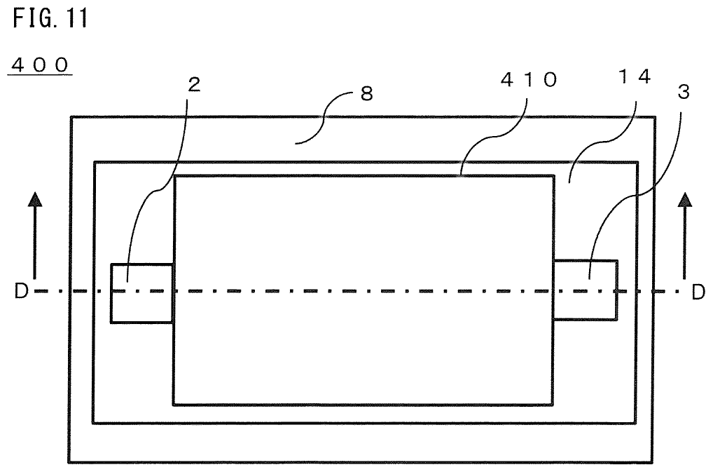

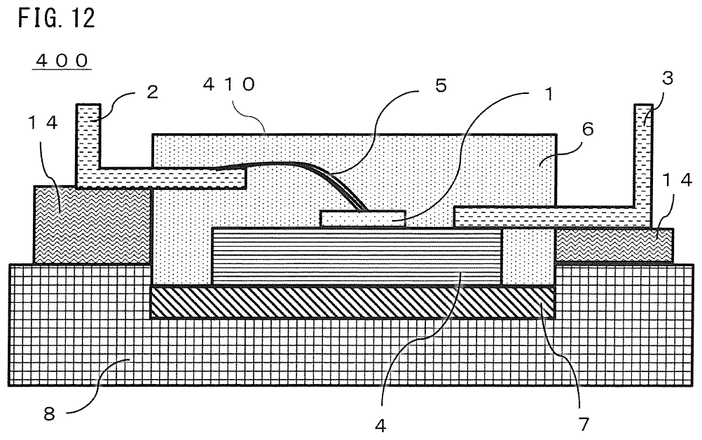

FIG. 11 shows a top view of a semiconductor device 400 according to embodiment 4, and FIG. 12 shows a sectional view along line D-D in FIG. 11. As shown in FIG. 11 and FIG. 12, the semiconductor device 400 of embodiment 4 is configured such that an insulation block 14 is provided between the first electrode terminal 2 and the heat sink 8 and between the second electrode terminal 3 and the heat sink 8 in the semiconductor device 100 of embodiment 1. Preferably, the insulation block 14 is provided, with no gaps, at least between the first electrode terminal 2 and the heat sink S and between the second electrode terminal 3 and the heat sink 8, and is formed in contact with a semiconductor package 410, the first electrode terminal 2, and the second electrode terminal 3. As shown in the top view in FIG. 11, the insulation block 14 is formed in a larger area than an area occupied by the first electrode terminal 2 and the second electrode terminal 3, whereby the creeping distances between the first electrode terminal 2 and the heat sink 8 and between the second electrode terminal 3 and the heat sink 8 can be extended by the insulation block 14. As a material of the insulation block 14, resin having a high insulation property is preferably used, and resin such as epoxy, polyimide, polyamide, or polyamide-imide, or a mixture obtained by adding silica, alumina, aluminum nitride, boron nitride, or the like to resin such as epoxy, polyimide, polyamide, or polyamide-imide, is used. Here, the same effects are obtained as long as a material of the insulation block 14 has a relative permittivity of 20 or less and a volume resistivity of 10¹⁰ Ω·cm or greater in a driving temperature range of the semiconductor device.

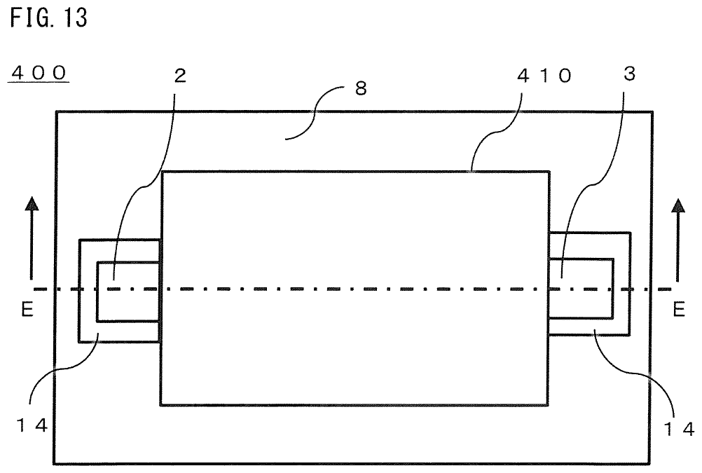

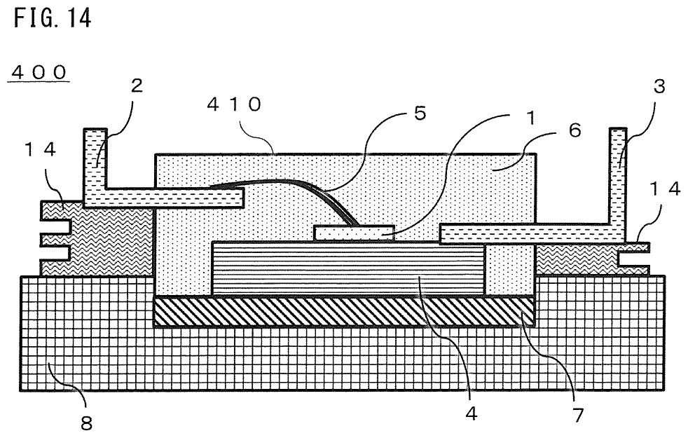

FIG. 13 shows a top view of the semiconductor device 400 according to a modification of embodiment 4, and FIG. 14 shows a sectional view along line E-E in FIG. 13. As shown in FIG. 13, also in the modification of embodiment 4, insulation blocks 14 are provided, with no gaps, at least between the first electrode terminal 2 and the heat sink 8 and between the second electrode terminal 3 and the heat sink 8. A difference from embodiment 4 is that, as shown in FIG.

14, the insulation block 14 between the first electrode terminal 2 and the heat sink 8, and the insulation block 14 between the second electrode terminal 3 and the heat sink 8, each have, at least at a surface forming a creeping path, a groove recessed in parallel to a joining plane between the heat sink 8 and the insulation block 14. Since the insulation block 14 between the first electrode terminal 2 and the heat sink 8, and the insulation block 14 between the second electrode terminal 3 and the heat sink 8, each have, at least at a surface forming a creeping path, a groove recessed in parallel to the joining plane between the heat sink 8 and the insulation block 14, the creeping distance between the first electrode terminal 2 and the heat sink 8, and the creeping distance between the second electrode terminal 3 and the heat sink 8, are extended as compared to a case of not having grooves. Although the example in which the insulation blocks 14 have grooves is shown in the modification of embodiment 4, it suffices that the creeping distance between the first electrode terminal 2 and the heat sink 8, and the creeping distance between the second electrode terminal 3 and the heat sink 8, are extended, and therefore, grooves formed in the insulation blocks 14 may be replaced with ridges protruding in parallel to the joining plane between the heat sink 8 and the insulation block 14, or a groove and a ridge may be used in combination.

In the semiconductor device configured as described above, since the semiconductor package is joined via the insulation sheet to the recess formed in the heat sink, the heat sink is joined without being covered by the semiconductor package. In addition, since the semiconductor package is supported by the side wall of the recess, displacement and separation of joining parts of the semiconductor package, the insulation sheet, and the heat sink are prevented. Further, the semiconductor device according to the present embodiment includes the insulation block provided in the space through which the heat sink and at least a part of the first electrode terminal that protrudes from the semiconductor package are opposed to each other, and in the space through which the heat sink and at least a part of the second electrode terminal that protrudes from the semiconductor package are opposed to each other. Thus, the insulation block contacts with the semiconductor package and fills the space between the first electrode terminal and the heat sink, and the space between the second electrode terminal and the heat sink. Therefore, while displacement between the semiconductor package and the heat sink is prevented, the spatial distance between the heat sink and each of the first electrode terminal and the second electrode terminal can be ensured and the external creeping distance therebetween can be extended. In addition, in the semiconductor device according to the present embodiment, the insulation block may have, at least at each of surfaces forming creeping paths between the first electrode terminal and the heat sink and between the second electrode terminal and the heat sink, a groove recessed or a ridge protruding, in parallel to the joining plane between the heat sink and the insulation block. Thus, as compared to a case of not having grooves or ridges, the creeping distances from the first electrode terminal and the second electrode terminal to the heat sink can be further extended.

Thus, the semiconductor device described in embodiment 4 and the modification thereof can provide a semiconductor device in which displacement between a semiconductor package and a heat sink is further prevented and an insulation property between the heat sink and each of a first electrode terminal and a second electrode terminal is further improved, in addition to the same effects as in embodiment 1.

### DESCRIPTION OF THE REFERENCE CHARACTERS

1 semiconductor chip
2 first electrode terminal
3 second electrode terminal
4 heat spreader
5 wire
6 sealing resin
7 insulation sheet
8 heat sink
9 semiconductor chip
10 third electrode terminal
11 heat spreader
12 bridge
13 protrusion
14 insulation block
100 semiconductor device
110 Semiconductor package
200 semiconductor device
210 semiconductor package
300 semiconductor device
310 semiconductor package
320 semiconductor, package
400 semiconductor device
410 semiconductor package

1. A semiconductor device comprising:
a semiconductor package in which a heat spreader, a semiconductor chip provided on one surface of the heat spreader, and an electrode terminal electrically connected to the semiconductor chip are sealed with resin, the semiconductor package having a bottom surface at which another surface of the heat spreader is exposed from the sealing resin, the electrode terminal protruding from at least one of a side surface and a top surface:
an insulation sheet provided at the bottom surface of the semiconductor package: and
a heat sink having a recess in which the bottom surface of the semiconductor package is stored, a depth of the recess being greater than a thickness of the insulation sheet, a bottom surface of the recess and the bottom surface of the semiconductor package being joined to each other via the insulation sheet, thus supporting the semiconductor package in the recess,
wherein
the semiconductor package has a protrusion continuously formed at a constant height or a plurality of protrusions having equal heights, the protrusion or the plurality of protrusions being formed by the sealing resin on a plane including a surface of the heat spreader that contacts with the insulation sheet, and protruding toward the bottom surface of the recess from a plane including a surface of the heat spreader that contacts with the insulation sheet,
the protrusion or the plurality of protrusions contact with the bottom surface of the recess not via the insulation sheet, and
the other surface of the heat spreader presses the insulation sheet, and the other surface of the heat spreader is joined to the bottom surface of the recess via the insulation sheet.

2. The semiconductor device according to claim 1, comprising two or more electrode terminals as the electrode terminal.

3. The semiconductor device according to claim 1, wherein
at least one electrode terminal protrudes from at least one side surface of the semiconductor package, and the depth of the recess is smaller than a minimum length from the electrode terminal protruding from the side surface, to the bottom surface of the semiconductor package.

4. The semiconductor device according to claim 3, further comprising an insulation block provided in a space through which the electrode terminal protruding from the side surface and the heat sink are opposed to each other.

5. The semiconductor device according to claim 4, wherein
the insulation block has, at least at a surface forming a creeping path between the heat sink and the electrode terminal protruding from the side surface, a groove recessed or a ridge protruding, in parallel to a joining plane between the heat sink and the insulation block.

6. (canceled)

7. The semiconductor device according to claim 1, wherein
the insulation sheet includes silicone rubber, urethane rubber, or thermosetting elastomer.

8. The semiconductor device according to claim 2, wherein
at least one electrode terminal protrudes from at least one side surface of the semiconductor package, and the depth of the recess is smaller than a minimum length from the electrode terminal protruding from the side surface, to the bottom surface of the semiconductor package.

9. The semiconductor device according to claim 8, further comprising an insulation block provided in a space through which the electrode terminal protruding from the side surface and the heat sink are opposed to each other.

10. The semiconductor device according to claim 9, wherein
the insulation block has, at least at a surface forming a creeping path between the heat sink and the electrode terminal protruding from the side surface, a groove recessed or a ridge protruding, in parallel to a joining plane between the heat sink and the insulation block.

11. The semiconductor device according to claim 2, wherein
the insulation sheet includes silicone rubber, urethane rubber, or thermosetting elastomer.

12. The semiconductor device according to claim 3, wherein
the insulation sheet includes silicone rubber, urethane rubber, or thermosetting elastomer.

13. The semiconductor device according to claim 4, wherein
the insulation sheet includes silicone rubber, urethane rubber, or thermosetting elastomer.

14. The semiconductor device according to claim 5, wherein
the insulation sheet includes silicone rubber, urethane rubber, or thermosetting elastomer.

15. The semiconductor device according to claim 8, wherein
the insulation sheet includes silicone rubber, urethane rubber, or thermosetting elastomer.

16. The semiconductor device according to claim 9, wherein
the insulation sheet includes silicone rubber, urethane rubber, or thermosetting elastomer.

17. The semiconductor device according to claim 10, wherein
the insulation sheet includes silicone rubber, urethane rubber, or thermosetting elastomer
